(19) United States
(12) Patent Application Publication
(10) Pub. No.: US 2015/0211116 A1
(43) Pub. Date: Jul. 30, 2015

(54) SUBSTRATE PROCESSING DEVICE

(71) Applicant: EUGENE TECHNOLOGY CO., LTD., Gyeonggi-do (KR)

(72) Inventors: Il-Kwang Yang, Gyeonggi-do (KR); Byoung-Gyu Song, Gyeonggi-do (KR); Kyong-Hun Kim, Gyeonggi-do (KR); Yong-Ki Kim, Chungcheongnam-do (KR); YangSik Shin, Gyeonggi-do (KR)

(73) Assignee: EUGENE TECHNOLOGY CO., LTD., Gyeonggi-do (KR)

(21) Appl. No.: 14/419,762

(22) PCT Filed: Aug. 23, 2013
(86) PCT No.: PCT/KR2013/007571

§ 371 Date: Feb. 5, 2015

(30) Foreign Application Priority Data
Aug. 28, 2012 (KR) 10-2012-0094384

(51) Int. Cl. C23C 16/455; C23C 16/44

(52) U.S. Cl. CPC C23C 16/455; C23C 16/45559; C23C 16/45519; C23C 16/4412

(57) ABSTRACT

Provided is a substrate processing apparatus. The substrate processing apparatus in which a process with respect to a substrate is performed includes a main chamber having an opened upper side, the main chamber including a passage defined in a side thereof so that the substrate is loaded or unloaded through the passage, a susceptor disposed within the main chamber to allow the substrate to be placed thereon, a chamber cover disposed on the opened upper side of the main chamber, the chamber cover including an upper installation space defined above the susceptor and a gas supply passage disposed outside the upper installation space, a heating block disposed in the upper installation space to heat the substrate, and a gas supply port connected to the gas supply passage to supply a process gas into the process space.

### TECHNICAL FIELD

The present invention disclosed herein relates to an apparatus for processing a substrate, and more particularly, to a substrate processing apparatus in which a gas supply passage is defined in the upper outside of a substrate to supply a process gas into a process space.

### BACKGROUND ART

Uniform heat treatment of a substrate at a high temperature is required in a semiconductor device manufacturing process. Examples of the semiconductor device manufacturing process may include chemical vapor deposition and silicon epitaxial growth processes in which a material layer is deposited on a semiconductor substrate placed on a susceptor within a reactor in a gaseous state. The susceptor may be heated at a high temperature ranging from about 400° C. to about 1,250° C. by resistance heating, radio-frequency heating, and infrared heating. Also, a gas may pass through the reactor, and thus a deposition process may occur very close to a surface of the substrate by chemical reaction of the gas in a gaseous state. A desired product may be deposited on the substrate due to this reaction.

A semiconductor device includes a plurality of layers on a silicon substrate. The layers are deposited on the substrate through a deposition process. The deposition process has several important issues that are important to evaluate the deposited layers and select a deposition method.

First, one example of the important issues is ‘quality’ of each of the deposited layers. The ‘quality’ represents composition, contamination levels, defect density, and mechanical and electrical properties. The composition of the deposited layer may be changed according to deposition conditions. This is very important to obtain a specific composition.

Second, another example of the issues is a uniform thickness over the wafer. Specifically, a thickness of a layer deposited on a pattern having a nonplanar shape with a stepped portion is very important. Here, whether the thickness of the deposited film is uniform may be determined through a step coverage which is defined as a ratio of a minimum thickness of the film deposited on the stepped portion divided by a thickness of the film deposited on the pattern.

The other issue with respect to the deposition may be a filling space. This represents a gap filling in which an insulating layer including an oxide layer is filled between metal lines. A gap is provided to physically and electrically isolate the metal lines from each other. Among the issues, uniformity is one of very important issues with respect to the deposition process. A non-uniform layer may cause high electrical resistance on the metal lines to increase possibility of mechanical damage.

### DISCLOSURE

### Technical Problem

The present invention provides a substrate processing apparatus in which a gas supply passage is defined outside an upper installation space separated from a process space to supply a process gas.

The present invention also provides a substrate processing apparatus in which a heater is installed in an upper installation space separated from a process space to control a temperature of a substrate.

Further another object of the present invention will become evident with reference to following detailed descriptions and accompanying drawings.

### Technical Solution

Embodiments of the present invention provide substrate processing apparatuses, the substrate processing apparatus including: a main chamber having an opened upper side; a susceptor disposed within the main chamber to allow a substrate to be placed thereon; a chamber cover disposed on the opened upper side of the main chamber, the chamber cover including an upper installation space defined above the susceptor and a gas supply passage disposed outside the upper installation space; a heating block disposed in the upper installation space to heat the substrate; and a gas supply port connected to the gas supply passage to supply a process gas into the process space.

In some embodiments, the main chamber may comprise a passage defined in a side thereof so that the substrate is loaded or unloaded through the passage, the substrate processing apparatuses may further include an auxiliary gas nozzle disposed on a side of passage so as to be adjacent to the susceptor to spray an inert gas.

In other embodiments, the substrate processing apparatuses may further include a diffusion plate disposed on a lower end of the gas supply passage to diffuse the process gas supplied through the gas supply port.

In still other embodiments, each of the gas supply passage and the diffusion plate may have an arc shape that is concentric with the susceptor, each of the gas supply passage and the diffusion plate having a width that is substantially equal to a diameter of the substrate.

In even other embodiments, the main chamber may have a lower installation space that is recessed from a bottom surface of the main chamber and in which the susceptor is disposed, the substrate processing apparatuses may further include a nozzle ring disposed in the lower installation space to surround the susceptor, the nozzle ring spraying an inert gas upward.

In yet other embodiments, the main chamber may include an exhaust passage defined in a side opposite to the gas supply passage, and the substrate processing apparatuses may further include a flow guide disposed outside the susceptor to guide the process gas supplied from the gas supply passage toward the exhaust passage.

In further embodiments, the flow guide may include: a circular guide part having an arc shape that is concentric with the susceptor, the circular guide part having a plurality of guide holes through which the process gas passes; and linear guide parts connected to both sides of the circular guide part and disposed on both sides of the susceptor, respectively, each of the linear guide parts having a guide surface that is substantially parallel to a straight line connecting a center of the gas supply passage to a center of the exhaust passage.

In still further embodiments, the main chamber may have a lower installation space that is recessed from a bottom surface of the main chamber and in which the susceptor is disposed, and the gas supply passage may be disposed above the bottom surface of the main chamber and outside the lower installation space.

### Advantageous Effects

According to the embodiment of the present invention, the heater may be installed in the upper installation space separated from the process space to control a temperature of the substrate. Also, the gas supply passage for supplying the process gas may be disposed outside the upper installation space to uniformly supply the process gas toward the substrate in one direction.

### DESCRIPTION OF DRAWINGS

FIG. 1 is a schematic view of a substrate processing apparatus according to an embodiment of the present invention;

FIG. 2 is a view illustrating a flow of a process gas while the substrate processing apparatus of FIG. 1 performs processes; and

FIG. 3 is a cross-sectional view illustrating a flow of a process gas within a process space of FIG. 2.

### BEST MODE

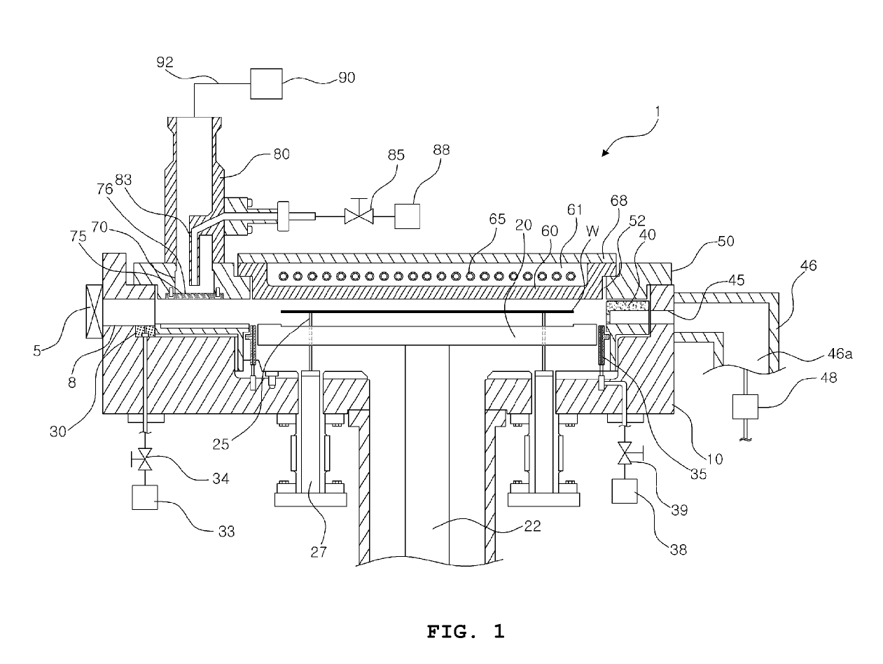

Hereinafter, exemplary embodiments of the present invention will be described in detail with reference to FIGS. 1 to 3. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration. Also, although a substrate is described as an example, the present invention is applicable to various objects to be processed.

FIG. 1 is a schematic view of a substrate processing apparatus according to an embodiment of the present invention. Referring to FIG. 1, a substrate processing apparatus 1 includes a main chamber 10 and a chamber cover 50. The main chamber 10 has an opened upper side. Also, a passage 8 through which a substrate W is accessible is defined in a side of the main chamber 10. A gate valve 5 is disposed outside the passage 8. The passage 8 may be opened or closed by the gate valve 5. A susceptor 20 is installed within the main chamber 10 to heat the substrate W placed thereon. The susceptor 20 may have a disc shape corresponding to that of the substrate W. The substrate W may be seated on an upper surface of the susceptor 20 to perform a deposition process. A lift pin 25 may pass through the susceptor 20. The substrate W transferred through the passage 8 is loaded on an upper portion of the lift pin 25. The lift pin 25 may be elevated by a lift pin driving part 27. When the substrate W is loaded, the lift pin driving part 27 may descend to allow the substrate W to be seated on the susceptor 20.

The chamber cover 50 is disposed on an opened upper side of the main chamber 10. The main chamber 10, the chamber cover 50, and a heating block 60 that will be described later may provide a inner space that is blocked from the outside. The substrate W is loaded into the process space through the passage 8. Processes with respect to the substrate W may be performed within the process space. The chamber cover 50 is disposed above the susceptor 20 to provide an upper installation space separated from the process space.

The heating block 60 heating the substrate W from an upper side of the substrate W is disposed in the upper installation space 52. The heating block 60 has an opened upper side. A heating block cover 68 closes the opened upper side of the heating block 60 to isolate the inside of the heating block 60 from the outside. Thus, an accomodating space 61 defined inside the heating block 60 is separated from the inner space as well as is blocked from the outside. A heater 65 is disposed in the accomodating space 61. A kanthal heater may be used as the heaters 65. Kanthal may be a Fe—Cr—Al alloy, wherein iron is used as a main material. Thus, kanthal may have high heat-resistance and electric-resistance.

Also, a worker may open the heating block cover 68 to approach the heater 65. Thus, the heater 65 may be easily maintained and repaired. Here, since the accomodating space 61 is separated from the process space, it may be unnecessary to convert a vacuum state of the process space into an atmospheric state when the heater 65 is maintained and repaired. That is, the accommodating space 61 in the atmospheric state is accessed by the heating block cover 68 to maintain and repair the heater 65.

The heating block 60 is heated by the heater 65 disposed in the accommodating space 61. Also, the substrate W may be heated by one or both of the heating block 60 and a heater disposed within the susceptor 20. That is, the substrate W is in contact with the susceptor 20 to be heated by a conduction, and the substrate W is heated by a radiation of the heating block 60. In the case of the conduction, the heat is transferred by contact, thus, the susceptor 20 can transfer a lot of heat to the substrate W. On the other hand, the heat flux is dependent on the position of the heater installed in the susceptor 20, thus, the heat flux transferred to the substrate W is different from each other and the heat deviation by a portion of the substrate W is inevitable. But, in the case of the radiation, the heat is transferred by an electromagnetic wave, thus, the heating block 60 cannot transfer a lot of heat to the substrate W. On the other hand, the heating block 60 can minimize the heat deviation irrespective of the arrangement of the heater 65. Therefore, the heat deviation can be minimized by the heating block 60 positioned above the substrate W and the susceptor 20 positioned below the substrate W.

The susceptor 20 and the heating block 60 are arranged in a direction substantially parallel to the substrate W. Also, each of the susceptor 20 and the heating block 60 may have a surface facing the substrate W and having an area greater than that of the substrate W to uniformly heat the substrate W. Also, each of the susceptor 20 and the heating block 60 may have a circular disk shape corresponding to that of the substrate W. Thus, the substrate W may be heated from upper and lower sides thereof to minimize the heat deviation with respect to the substrate W, thereby preventing causes of process non-uniformity on the substrate W and thickness deviation of a deposited thin film from occurring.

Also, since the substrate W is heated from the upper and lower sides thereof, a time required for heating the substrate W to a process temperature may be reduced and a warpage of the substrate W caused by heating is prevented. If only the lower surface of the substrate W is heated by the susceptor 20, the degree of the thermal expansion is different in the upper surface of the substrate W and the lower surface of the substrate W, thus, the warpage of the substrate W is occurred by the difference of the thermal expansion. But, the upper surface of the substrate W and the lower surface of the substrate W are heated at the same time, the warpage of the substrate W can be prevented.

Also, a gas supply passage 70 is defined outside the upper installation space of the chamber cover 50. The gas supply passage 70 is defined in the chamber cover 50, the gas supply passage 70 is positioned between the passage 8 and the process space C. A gas supply port 80 is disposed in an upper end of the gas supply passage 70. A process gas supply tube 83 is inserted into a side of the gas supply port 80 to supply the process gas into the substrate processing apparatus 1 through the gas supply port 80. The process gas supply tube 83 is connected to a process gas storage tank 88 to supply the process gas into the substrate processing apparatus 1. Here, a process gas supply valve 85 may be opened or closed to adjust an input amount of process gas. Also, the gas supply port 80 may supply plasma into the chamber through a cleaning gas supply tube 92 connected to a remote plasma system (RPS) 90.

A diffusion plate 75 is disposed on a lower end of the gas supply passage 70. The diffusion plate 75 has a plurality of diffusion holes 76 to diffuse the process gas supplied through the process gas supply tube 83 into the inner space of the main chamber 10. Since each of the diffusion holes 76 is inclined downward toward an exhaust passage 45, the process gas supplied into the process space through the diffusion plate 75 may flow toward the exhaust passage 45 defined in a side opposite to the passage 8. The exhaust passage 45 is connected to an exhaust pump 48 through an exhaust port 46 to discharge forcibly the process gas introduced into the process space to the outside.

An auxiliary gas nozzle 30 is disposed outside the diffusion plate 75. The auxiliary gas nozzle 30 may spray an inert gas supplied from a first inert gas storage tank 33 into the inner space, so that the process gas introduced through the diffusion plate 75 is diffused toward the substrate W and the process gas is prevented from flowing to the passage 8. The main chamber 10 has a lower installation space D, the lower installation space D is recessed from a bottom surface of the main chamber 10 and the susceptor 20 is disposed in the lower installation space D. The susceptor 20 and a nozzle ring 35 disposed along a circumference of the susceptor 20 are disposed in the lower installation space. The nozzle ring 35 is disposed between the susceptor 20 and the bottom surface of the chamber body 10 to spray the inert gas, thereby preventing the process gas from being introduced through a gap between the susceptor 20 and the bottom surface of the chamber body 10. The nozzle ring 35 receives an inert gas from a second inert gas storage tank 38 to spray the inert gas upward, like the auxiliary gas nozzle 30.

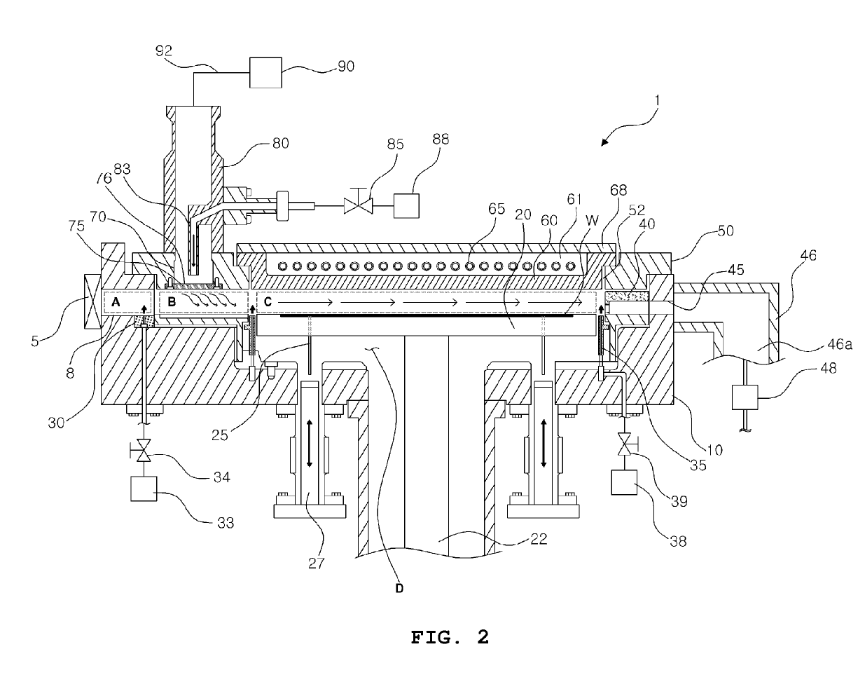

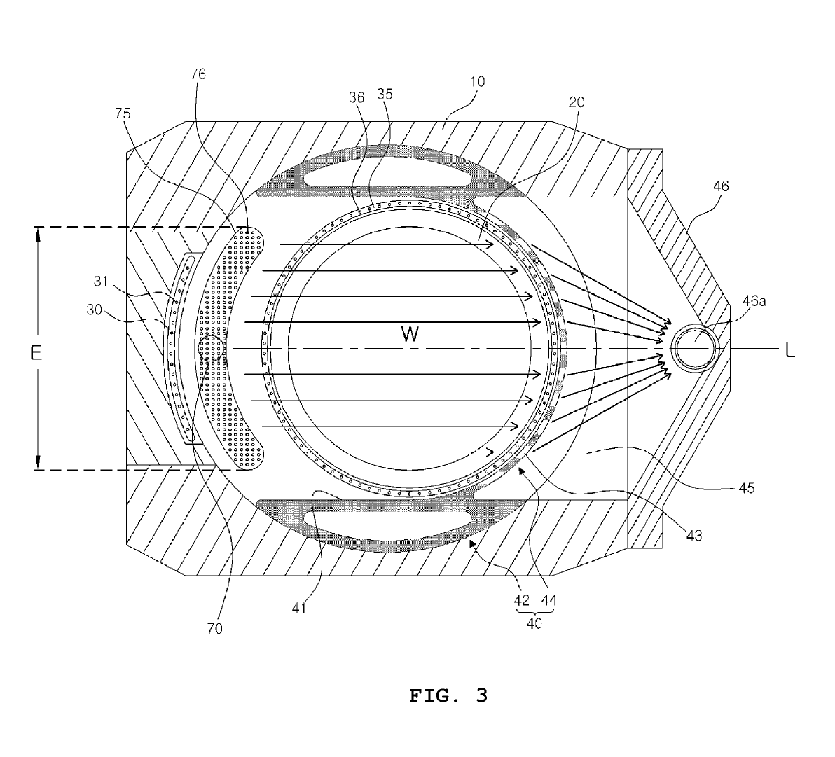

A flow guide 40 may be disposed outside the susceptor 20 to guide a flow of the process gas from the gas supply passage 70 toward the exhaust passage 45. That is, according to the present invention, the process gas supply tube 83 may be disposed outside the substrate W so that the process gas is deposited while passing through the substrate W. A flow of the process gas during the processing and a flow of the process gas through the flow guide 40 will be described with reference to FIGS. 2 and 3.

FIG. 2 is a view illustrating a flow of a process gas while the substrate processing apparatus of FIG. 1 performs processes, and FIG. 3 is a cross-sectional view illustrating a flow of a process gas within a process space of FIG. 2. Referring to FIG. 2, an inner space of the main chamber 10 may be partitioned into a passage section A having the passage 8 through which the substrate W enters through a gate, a diffusion section B disposed between the passage 8 and the susceptor 20 and having the gas supply passage 70, a process section C disposed above the susceptor 20 in which the process with respect to the substrate W is performed, and a lower installation space D disposed below the process section C in which the susceptor 20 and the nozzle ring 35 are disposed.

As described above, the exhaust passage 45 is defined in a side opposite to the gas supply passage 70. Thus, the process gas is pumped by the exhaust pump 48 connected to the exhaust passage 45 to flow toward the exhaust passage 45. In addition, the auxiliary gas nozzle 30 is disposed on the passage section A to spray the inert gas so that the process gas introduced into the diffusion section B through the diffusion plate 75 flows toward the process section C. Thus, the process gas introduced into the diffusion section B flows toward the exhaust passage 45 via the substrate W.

Referring to FIG. 3, the process gas supplied through the gas supply passage 70 is diffused into the process space by the plurality of diffusion holes 76 defined in the diffusion plate 75. The lower end of the gas supply passage 70 (or the diffusion plate 75) is disposed above the bottom surface of the main chamber, the process gas is discharged through the diffusion plate 75 and diffused, in sequence, the process gas collides with the bottom surface of the main chamber 10 and diffused by the kinematic energy of the process gas. The diffused process gas flows toward the process section C. Thus, the process gas is fully diffused and flows to the process section C, the process can be uniformly performed in a center region of the substrate W and an edge region (adjacent to the flow guide 40) of the substrate W, irrespective of the position of the gas supply passage 70.

The diffusion plate 75 has an arc shape that is concentric with the susceptor. Also, the auxiliary gas nozzle 30 disposed outside the diffusion plate 75 may have an arc shape corresponding to that of the diffusion plate 75. Each of the diffusion plate 75 and the gas supply passage on which the diffusion plate 75 is disposed may have a width E substantially corresponding to a diameter of the substrate W to diffuse the process gas onto the substrate W. Since the inert gas is sprayed upward from the auxiliary gas nozzle 30 to prevent the process gas introduced through the diffusion plate 75 from flowing toward the passage 8, the most of process gas may be used for the processes with respect to the substrate W.

Also, as described above, since the nozzle ring 35 surrounding the circumference of the susceptor 20 is disposed to prevent the process gas from being introduced into a space between the susceptor 20 and the main chamber 10, the inert gas may be sprayed into the process space through a plurality of second spray holes 36 defined in the nozzle ring 35. Thus, the process gas supplied through the diffusion plate 75 may be used for the processes with respect to the substrate W.

That is to say, the process gas introduced through the diffusion plate 75 is pumped by the exhaust pump 48 connected to the exhaust passage 45 to flow toward the exhaust passage 45. Generally, the substrate processing apparatus 1 in which the processes with respect to the substrate W are performed may have a process space corresponding to a shape of the substrate W. Since the substrate W has a circular disk shape, the process space may also have a circular disk shape corresponding to that of the substrate W. Thus, since the process space has the circular disk shape, a space in which the substrate W does not react with the process gas may be generated.

For this, a flow guide 40 may be provided to reduce the space in which the substrate W does not react with the process gas and guide a uniform flow of the process gas toward the exhaust passage 45. Since the process gas flows toward the exhaust passage 45, it may be necessary to guide the process gas so that the process gas is uniformly distributed on a surface of the substrate W to uniformly react on the substrate W. Thus, the flow guide 40 includes a linear guide part 42 disposed in the main chamber 10 and outside the nozzle ring 35 to reduce a space in which the substrate W does not react with the process gas and a circular guide part 44 having a plurality of guide holes for guiding the process gas to uniformly flow toward the exhaust passage 45.

The circular guide part 44 is disposed on a side opposite to the diffusion plate 75 and has an arc shape corresponding to that of the nozzle ring 35 adjacent thereto. The circular guide part 44 has the plurality of guide holes 43 at a preset distance to guide the process gas introduced through the diffusion plate 75 to uniformly flow toward the substrate W.

The linear guide part 42 is connected to the circular guide part 44 and disposed on each of both sides of the susceptor 20. As illustrated in FIG. 3, the linear guide part 42 has a guide surface 41, the guide surface 41 is substantially parallel to a straight line L that connects a center of the gas supply passage 70 to a center of a center of the exhaust passage 45 (or an exhaust hole 46a). The linear guide part 42 guides the process gas to linearly flow from the diffusion plate 75 toward the circular guide part 44 in a direction parallel to each other. Also, since the volume of the process space C is minimized by the linear guide part 42, the reactivity between the process gas and the substrate W may be improved and the consumption of the process gas may be minimized.

Thus, according to the present invention, the process gas may be supplied outside the substrate W to perform the deposition process. Thus, a limitation in which it is difficult to uniformly supply a process gas onto a substrate W due to the large-scaled substrate W in recent years may be overcome. Also, since the substrate W is heated by using the heating block 60 and the susceptor 20 which are respectively disposed above and below the substrate W, temperature gradient may be controlled to prevent warpage of the substrate W from occurring. In addition, the flow guide 40 may be disposed in the main chamber 10 to substantially reduce the process space in which the processes with respect to the substrate W are performed. Also, the flow guide 40 may uniformly guide the process gas onto the substrate W to improve process uniformity on the central and edge portions of the substrate W.

According to the embodiment of the present invention, the heater may be installed in the upper installation space separated from the process space to control a temperature of the substrate. Also, the gas supply passage for supplying the process gas may be defined outside the upper installation space to uniformly supply the process gas toward the substrate in one direction.

Although the present invention is described in detail with reference to the exemplary embodiments, the invention may be embodied in many different forms. Thus, technical idea and scope of claims set forth below are not limited to the preferred embodiments.

### INDUSTRIAL APPLICABILITY

The present invention is applicable for a semiconductor manufacturing apparatus and a semiconductor manufacturing method in a various type.

What is claimed is:

1. A substrate processing apparatus comprising:
a main chamber having an opened upper side;
a susceptor disposed within the main chamber to allow a substrate to be placed thereon;
a chamber cover disposed on the opened upper side of the main chamber, the chamber cover comprising an upper installation space defined above the susceptor and a gas supply passage disposed outside the upper installation space;
a heating block disposed in the upper installation space to heat the substrate; and
a gas supply port connected to the gas supply passage to supply a process gas into the process space.

2. The substrate processing apparatus of claim 1, wherein the main chamber comprises a passage defined in a side thereof so that the substrate is loaded or unloaded through the passage,
the substrate processing apparatus further comprises an auxiliary gas nozzle disposed on a side of the passage so as to be adjacent to the susceptor to spray an inert gas.

3. The substrate processing apparatus of claim 1, further comprising a diffusion plate disposed on a lower end of the gas supply passage to diffuse the process gas supplied through the gas supply port.

4. The substrate processing apparatus of claim 3, wherein each of the gas supply passage and the diffusion plate has an arc shape that is concentric with the susceptor, each of the gas supply passage and the diffusion plate having a width that is substantially equal to a diameter of the substrate.

5. The substrate processing apparatus of claim 3, wherein the main chamber has a lower installation space that is recessed from a bottom surface of the main chamber and in which the susceptor is disposed,
the substrate processing apparatus further comprises a nozzle ring disposed in the lower installation space to surround the susceptor, the nozzle ring spraying an inert gas upward.

6. The substrate processing apparatus of claim 1, wherein the main chamber comprises an exhaust passage defined in a side opposite to the gas supply passage, and
the substrate processing apparatus further comprises a flow guide disposed outside the susceptor to guide the process gas supplied from the gas supply passage toward the exhaust passage.

7. The substrate processing apparatus of claim 6, wherein the flow guide comprises:
a circular guide part having an arc shape that is concentric with the susceptor, the circular guide part having a plurality of guide holes through which the process gas passes; and
linear guide parts connected to both sides of the circular guide part and disposed on both sides of the susceptor, respectively, each of the linear guide parts having a guide surface that is substantially parallel to a straight line connecting a center of the gas supply passage to a center of the exhaust passage.

8. The substrate processing apparatus of claim 1, wherein the main chamber has a lower installation space that is recessed from a bottom surface of the main chamber and in which the susceptor is disposed, and
the gas supply passage is disposed above the bottom surface of the main chamber and outside the lower installation space.
